(19) United States
(12) Patent Application Publication
(10) Pub. No.: US 2026/0048678 A1
(43) Pub. Date: Feb. 19, 2026

(54) SYSTEMS AND METHODS FOR MANAGING AND PREDICTING MAINTENANCE SERVICES FOR EV CHARGING ARRAYS

(71) Applicant: WattsUp Technologies, Bozeman, MT (US)

(72) Inventors: Hilary Ann Taylor, Phoenix, AZ (US); Audrey Katherine Wooding, Bozeman, MT (US); Sean Thomas Lamont, St. Petersburg, FL (US)

(21) Appl. No.: 19/300,104

(22) Filed: Aug. 14, 2025

Related U.S. Application Data
(60) Provisional application No. 63/682,898, filed on Aug. 14, 2024.

(51) Int. Cl. B60L 53/67; B60L 53/62; G01R 31/56; G06Q 10/04; G06Q 10/0631; G06Q 10/20

(52) U.S. Cl. CPC B60L 53/67; B60L 53/62; G01R 31/56; G06Q 10/04; G06Q 10/06315; G06Q 10/20

(57) ABSTRACT

A system for monitoring and maintaining electric vehicle (EV) chargers including at least one memory for storing computer-executable instructions and at least one processor for executing the instructions stored on the at least one memory. Execution of the instructions programs the at least one processor to perform operations that include receiving input data associated with at least one EV charger, monitoring the input data via at least one artificial intelligence (AI) model, detecting an anomaly in the input data, wherein the anomaly corresponds to a predicted failure of at least one component of the at least one EV charger, automatically scheduling a repair, in response to a determination that the repair has been completed, collecting feedback from at least one technician associated with the repair, and providing the feedback to the at least one AI model, wherein the feedback is used to continuously train the at least one AI model.

### CROSS REFERENCE TO RELATED APPLICATIONS

This application claims priority to U.S. Provisional Patent Application No. 63/682,898, filed on Aug. 14, 2024 and titled “SYSTEMS AND METHODS FOR MANAGING AND PREDICTING MAINTENANCE SERVICES FOR EV CHARGING ARRAYS,” the entire disclosure of which is hereby incorporated by reference.

### TECHNICAL FIELD

This specification relates to electric vehicle (EV) chargers and, in particular, to platforms for managing and predicting maintenance services for EV chargers.

### BACKGROUND

The electric vehicle (EV) charging industry relies heavily on a large ecosystem of EV chargers to operate efficiently. Such chargers require regular maintenance by skilled electricians or technicians to prevent unexpected failures and prolong their lifespan. Typically, maintenance approaches are performed in a reactive manner, addressing problems or failures only when or after they happen. This often results in unplanned downtime and costly expert repairs. As such, there is a need for a system that can monitor hardware health in real-time, predict maintenance needs, and automate the maintenance process.

### SUMMARY

At least one aspect of the present disclosure is directed to a system for monitoring and maintaining electric vehicle (EV) chargers. The system includes at least one memory for storing computer-executable instructions and at least one processor for executing the instructions stored on the at least one memory. Execution of the instructions programs the at least one processor to perform operations that include receiving input data associated with at least one EV charger, monitoring the input data via at least one artificial intelligence (AI) model, detecting, via the at least one AI model, an anomaly in the input data, wherein the anomaly corresponds to a predicted failure of at least one component of the at least one EV charger, automatically scheduling a repair, in response to a determination that the repair has been completed, collecting feedback from at least one technician associated with the repair, and providing the feedback to the at least one AI model, wherein the feedback is used to continuously train the at least one AI model to improve the accuracy of the at least one AI model.

In some embodiments, execution of the instructions programs the at least one processor to perform operations that include automatically ordering a replacement component. In some embodiments, the replacement component is used in the repair. In some embodiments, automatically scheduling a repair includes scheduling a repair based on (i) an availability of at least one technician and (ii) a lead time of the replacement component. In some embodiments, execution of the instructions programs the at least one processor to perform operations that include determining that the at least one AI model inaccurately detected an anomaly based on the feedback from the at least one technician associated with the repair and in response to the determination, tuning the at least one AI model based on the inaccurate detection and the corresponding feedback.

In some embodiments, automatically scheduling a repair includes scheduling a repair based on a predicted failure date of the at least one component associated with the predicted failure. In some embodiments, receiving input data associated with the at least one EV charger includes receiving, or requesting to receive, input data at a predetermined interval. In some embodiments, receiving input data associated with the at least one EV charger includes receiving at least one of electrical data, operational data, environmental data, communication data, mechanical data, and user interaction data. In some embodiments, receiving input data associated with the at least one EV charger includes receiving input data from a user associated with the at least one EV charger. In some embodiments, execution of the instructions programs the at least one processor to perform operations that include generating an alert in response to detecting an anomaly that corresponds to a predicted failure of at least one component of the at least one EV charger and delivering the alert to at least one user associated with the at least one EV charger.

Another aspect of the present disclosure is directed to a method for monitoring and maintaining electric vehicle (EV) chargers. The method includes receiving input data associated with at least one EV charger, monitoring the input data via at least one artificial intelligence (AI) model, detecting, via the at least one AI model, an anomaly in the input data, wherein the anomaly corresponds to a predicted failure of at least one component of the at least one EV charger, automatically scheduling a repair, in response to a determination that the repair has been completed, collecting feedback from at least one technician associated with the repair, and providing the feedback to the at least one AI model, wherein the feedback is used to continuously train the at least one AI model to improve the accuracy of the at least one AI model.

In some embodiments, the method includes automatically ordering a replacement component. In some embodiments, the replacement component is used in the repair. In some embodiments, automatically scheduling a repair includes scheduling a repair based on (i) an availability of at least one technician and (ii) a lead time of the replacement component. In some embodiments, the method includes determining that the at least one AI model inaccurately detected an anomaly based on the feedback from the at least one technician associated with the repair and in response to the determination, tuning the at least one AI model based on the inaccurate detection and the corresponding feedback.

In some embodiments, automatically scheduling a repair includes scheduling a repair based on a predicted failure date of the at least one component associated with the predicted failure. In some embodiments, receiving input data associated with the at least one EV charger includes receiving, or requesting to receive, input data at a predetermined interval. In some embodiments, receiving input data associated with the at least one EV charger includes receiving at least one of electrical data, operational data, environmental data, communication data, mechanical data, and user interaction data. In some embodiments, receiving input data associated with the at least one EV charger includes receiving input data from a user associated with the at least one EV charger. In some embodiments, the method includes generating an alert in response to detecting an anomaly that corresponds to a predicted failure of at least one component of the at least one EV charger and delivering the alert to at least one user associated with the at least one EV charger.

### BRIEF DESCRIPTION OF THE DRAWINGS

FIG. 1 is a block diagram of an EV charger monitoring system 100 in accordance with aspects described herein;

FIG. 2 is a block diagram of an EV charger monitoring system 100 in accordance with aspects described herein;

FIG. 3 is a flow diagram of a method for automatically monitoring and maintaining EV chargers in accordance with aspects described herein; and

FIG. 4 is computing device.

### DETAILED DESCRIPTION

Maintaining the health of EV Chargers is crucial for optimal performance, longevity, and uptime. Monitoring and maintaining hardware health often requires significant manual intervention, leading to inefficiencies and increased downtime. Traditional methods of maintaining and monitoring hardware health involve periodic manual inspections and reactive maintenance, which are inefficient, costly, and unscalable. Further, periodic manual inspections often result in the discovery of a component failure after the failure has already occurred. In such cases, the component failure may have caused other damage or failures to occur that could have been avoided by early, prompt detection of the component failure (or impending failure).

As such, an improved system for real-time monitoring and predictive maintenance of EV chargers is provided herein. In some embodiments, the system leverages artificial intelligence (AI) or machine learning (ML) models to process incoming data, predict maintenance needs, and assess overall hardware health. In some embodiments, the system features a user-friendly interface for monitoring hardware information. The system continuously monitors device hardware data, analyzes that data with AI/ML models, predicts future hardware device failures, and automates the maintenance workflow. In some embodiments, the system includes an automated process for ordering components and scheduling technicians based on skill level, location, and/or availability for repairs. In some embodiments, technician feedback is collected to train, correct, or otherwise improve, AI/ML model predictions and diagnoses. In some embodiments, the system reduces downtime, enhances hardware performance, and optimizes maintenance workflows. In some cases, such proactive anticipation/detection can reduce repair costs by minimizing subsequent damage caused by neglected or unknown hardware failures.

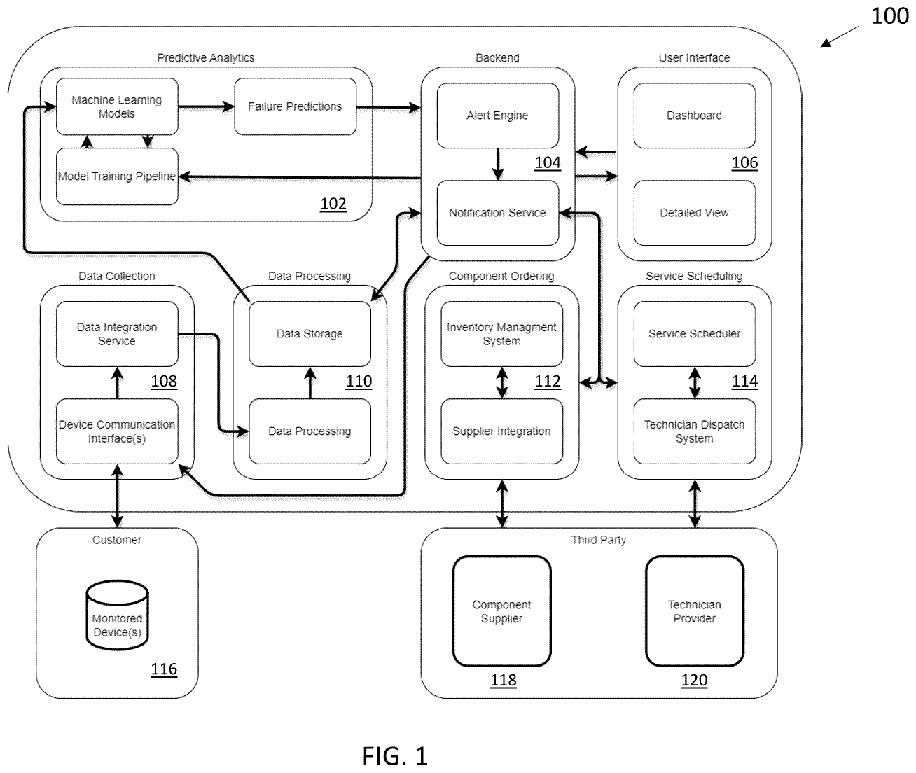

FIG. 1 is a block diagram of an EV charger monitoring system 100 in accordance with aspects described herein. As shown, the system 100 includes a predictive analytics module 102, a backend module 104, a user interface (UI) module 106, a data collection module 108, a data processing module 110, a component ordering module 112, and a service scheduling module 114. In some examples, the data collection module 108 includes one or more device communication interfaces that are configured to receive data associated with one or more monitored devices 116. In some examples, the monitored devices 116 are EV chargers. In some examples, the monitored devices are intermediate devices that monitor and collect data from EV chargers.

Data may be automatically provided from the monitored devices 116 to the data collection module 108 via the device communication interface (e.g., at a predetermined interval). In some examples, the data collection module 108 is configured to request data from the monitored devices 116 via the device communication interface (e.g., at a predetermined interval). In some examples, data is provided/requested at the same interval for each of the monitored devices 116. In some examples, the interval at which data is provided/requested varies based on the type of device 116. For example, some devices may have highly variable data that is monitored more frequently than devices that experience slower trends in data. In some examples, the data collection module 108 receives data from one or more users (e.g., inspectors, technicians, customers, etc.) regarding the monitored devices 116.

The data provided from the monitored devices 116 to the data collection module 108 may include, for example, (i) electrical data, such as voltage (e.g., input and output voltage levels), current (e.g., current flow during charging sessions), power consumption (e.g., power delivered to EVs), energy consumption (e.g., total energy dispensed over time), and power quality (e.g., harmonics, power factor, and transient voltages), (ii) operational data, such as charger status (e.g., online/offline status, availability, and operational mode usage), charging session data (e.g., start and end times, duration, energy delivered, and user details), usage patterns (e.g., frequency and duration of charging sessions and peak usage times), and error or fault codes (e.g., malfunctions and troubleshooting), (iii) environmental data, such as temperature (e.g., internal charger temperature and ambient temperature), humidity, and weather conditions, (iv) communication data, such as network connectivity (e.g., status of network connections to Wi-Fi, ethernet, cellular, etc.), data transmission logs (e.g., ensuring data is sent and received correctly), and software updates (e.g., status of firmware and software versions and update logs), (v) mechanical data, such as physical condition (e.g., wear and tear, damage, or vandalism) and connector status (e.g., condition and usage of charging connectors and cables), and (vi) user interaction data, such as user feedback (e.g., reported issues and satisfaction ratings). In some examples, the data is provided in accordance with the Open Charge Point Protocol (OCPP).

In some examples, the data collection module 108 includes a data integration service. The data integration service is configured to transport data from the data communication interface to the data processing module 110.

The data processing module 110 receives data from the data collection module 108 for processing and storage. In some examples, the data processing module 110 includes a data processing engine that is configured to format and normalize the incoming data. In some examples, the data processing module 110 includes a data storage engine. In some examples, the data storage engine includes a centralized database for storing the data. In some examples, the data store engine stores data in two or more different databases. In some examples, the data storage engine is configured to store data in one or more external databases (e.g., cloud-hosted storage).

The predictive analytics module 102 is configured to analyze data to predict the maintenance needs of the monitored devices 116. The predictive analytics module 102 evaluates the components and overall health of the monitored devices 116. In some examples, the predictive analytics module 102 includes one or more AI/ML models that are trained to analyze the data received from the monitored devices 116. In some examples, data is provided to the AI/ML models automatically by the data processing module 110 (or the data storage engine). In some examples, the predictive analytics module 102 is configured to request data from the data processing module 110 (e.g., at a periodic interval). The AI/ML model(s) output failure predictions based on the maintenance needs and overall health of the monitored devices 116.

The predictions output from the predictive analytics module 102 are provided to the backend module 104. In some examples, the backend module 104 includes an alert engine that generates alerts based on the predictions. The alert engine may compare the failure predictions to one or more thresholds to determine whether action is needed. For example, the alert engine may compare the predicted health of a component to a threshold that determines when the component should be serviced or replaced. In some examples, the thresholds are configured by a user (e.g., an operator of the system 100 or an operator of the monitored devices 116). In some examples, the alert engine compares the failure predictions to one or more predetermined diagnoses. The alert engine may identify one or more diagnoses that correspond to the symptoms (i.e., the failure predictions) output by the predictive analytics module 102. In some examples, at least one predetermined diagnosis corresponds to failures across multiple components of a monitored device 116.

In some examples, the backend module 104 includes a notification service that is configured to generate notifications based on the alerts generated by the alert engine. The notification service provides notifications to one or more users associated with the system 100. For example, the notification service may provide notifications to a system user (e.g., a technician or platform operator), a customer (e.g., the owner or operator of the monitored devices 116), or the monitored devices 116. In some examples, the UI module 106 is configured to receive notifications and present them to system users. The UI module 106 includes a dashboard engine that displays graphics and other information related to the notifications. The dashboard engine may allow users to monitor hardware health, view diagnostics, and monitor repair and maintenance processes. In some examples, the UI module 106 includes a detailed view engine that provides additional information regarding each notification. For example, the additional information may include recommended repairs and upgrades, service plans, component replacements, instructions for performing repairs, details related to the damaged the device, or details related to an event that caused the damage.

In some examples, the notification service provides notifications to one or more automated services. For example, the notification service may provide notifications to the component ordering module 112. In some examples, the notification includes a request to order one or more components for repairing or upgrading the monitored device 116. In some examples, the component ordering module 112 is configured to identify one or more components to order based on the notification (e.g., based on a failure or diagnosis represented by the notification). In some examples, the component ordering module 112 includes an inventory management system. The inventory management system is configured to manage an inventory of components that is under the control or available to the system operator, the customer, or the operator of the monitored devices 116. In some examples, notifications received by the component ordering module 112 are provided to the inventory management system to determine whether the required components are available. If the components are not available, the inventory management system may send a request to a supplier integration engine. In some examples, the supplier integration engine is configured to generate a component order that is delivered to one or more third-party component suppliers 118. The supplier integration engine manages the component orders and tracks lead times and deliveries. In some examples, the supplier integration engine arranges for delivery of the components at a desired location (e.g., the location of the monitored devices 116, the location of one or more technicians, or the location of the component inventory). Once the ordered components have been received, the supplier integration engine may notify the inventory management system.

The notification service may also provide notifications to the service scheduling module 114. In some examples, the service scheduling module 114 is configured to schedule or arrange services (e.g., repairs, upgrades, and inspections) to be performed on the monitored devices 116. In some examples, the service scheduling module 114 includes a service scheduler engine that is configured to identify and schedule services based on the notification (e.g., based on a failure or diagnosis represented by the notification). In some examples, the service scheduler engine arranges services based on an order in which they should be performed. In some examples, the services are scheduled based on a priority rank of a monitored device 116. In some examples, the services are scheduled based on an anticipated or predicted failure date of one or more components. The service scheduling module 114 may receive updates from the component ordering module 112 regarding component lead times, availability, and delivery. As such, the service scheduler engine may schedule services based on the availability of necessary components. In some examples, the service scheduling module 114 includes a technician dispatch system that is configured to request (or assign) technicians to perform the scheduled services. For example, the technician dispatch system may send requests to one or more third-party technician providers 120. In some examples, each request indicates one or more of the services scheduled by the service scheduler engine. Technicians may be requested or assigned based on skill level, certifications, locations, availability, and other relevant information for technicians. In some examples, the technician dispatch system receives scheduling availability from the technician provider 120 and provides updates to the service scheduler engine. In some examples, the service scheduler engine is configured to update the scheduled services based on technician availability.

Updates from the component ordering module 112 and the service scheduling module 114 may be forwarded to the backend module 104. In some examples, the notification service of the backend module 104 generates one or more notifications that are delivered to the UI module 106 (e.g., a service has been scheduled or completed, a component has been ordered or delivered, etc.). In some examples, the updates may be directed by the backend module 104 to the data processing module 110 for storage (e.g., via the data storage engine). In some examples, the updates are provided to a model training pipeline of the predictive analytics module 102. For example, post-repair statuses of the monitored devices 116 may be used to continuously train and improve the AI/ML models of the predictive analytics module 102. Likewise, feedback from technicians may be used in a similar manner to train and improve the AI/ML models.

In some examples, the feedback from technicians is used to determine (or measure) the accuracy of the anomaly detections or predicted failures of the AI/ML models. For example, the technician feedback may indicate that an anomaly was falsely detected or that a predicted failure was inaccurate or premature. In such cases, the input data associated with inaccurate detections or predictions may be assigned to a separate tuning dataset. This tuning dataset may be used to fine-tune the AI/ML models to correct the inaccurate detections/predictions that were previously made. In some examples, the corresponding technician feedback is included in the dataset or otherwise provided to the AI/ML models. The feedback may be used as the rationale that explains to the AI/ML models why the detections or predictions were inaccurate, such that the AI/ML model can improve its ability to accurately detect anomalies and predict component failures.

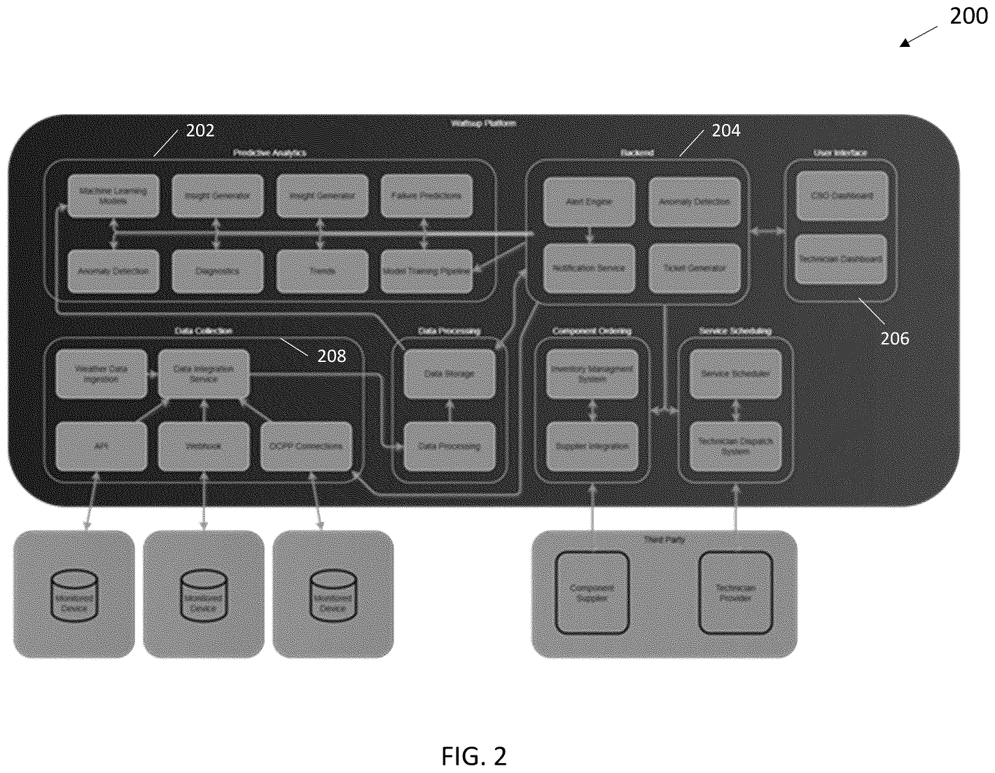

FIG. 2 is a block diagram of another EV charger monitoring system 200 in accordance with aspects described herein. The system 200 is substantially the same as the system 100 of FIG. 1, except the predictive analytics module 202, the backend module 204, the UI module 206, and the data collection module 208 include additional or different sub-modules. For example, the predictive analytics module 202 includes an anomaly detection sub-module, a diagnostics sub-module (and corresponding insight generator), and a trends sub-module (and corresponding insight generator). The backend module 204 includes an anomaly detection sub-module and a ticket generator. The UI module 206 includes a customer/operator dashboard and a technician dashboard. The data collection module 208 an application programming interface (API) sub-module, a webhook sub-module, and an OCPP connection sub-module for receiving and collecting data from monitored devices.

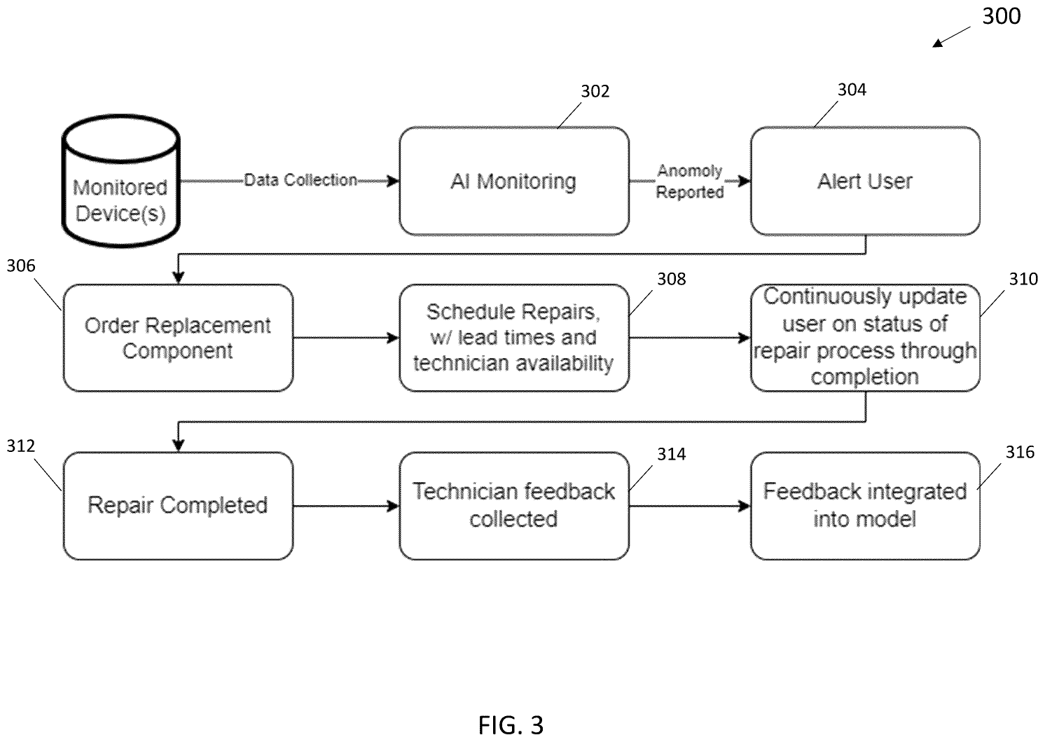

FIG. 3 is a flow diagram of a method 300 for automatically monitoring and maintaining EV chargers. In some examples, the method 300 is configured to be carried out using the system 100 of FIG. 1. It should be appreciated that the method 300 of FIG. 3 may alternatively be performed using the system 200 of FIG. 2.

At step 302, the system 100 receives input data associated with the monitored devices 116 for monitoring. As described above, the input data is received by the data collection module 108 and provided to the predictive analytics module 102 via the data processing module 110. The predictive analytics module 102 is configured to monitor the input data (e.g., via the one or more AI/ML models).

At step 304, an alert is sent to the user regarding an anomaly reported by the predictive analytics module 102. In some examples, the reported anomaly corresponds to a failure prediction output from the predictive analytics module 102. In some examples, the anomaly/failure is provided to the user as a notification via the backend module 104 and the UI module 106.

At step 306, the system 100 orders a replacement component based on the alert/notification. In some examples, the replacement component is ordered automatically by the component ordering module 112. In some examples, the component ordering module 112 waits for user confirmation (e.g., via the UI module 106) before proceeding with the order. It should be appreciated that not all repairs require new or replacement components. In such examples, step 306 may be optional or skipped altogether.

At step 308, the system 100 schedules a repair (or repairs) based on the alert/notification. In some examples, the repairs are scheduled by the service scheduling module 114 based on component lead time (e.g., as indicated by the component ordering module 112) and technician availability (e.g., as indicated by the third-party technician provider 120). In some examples, the repairs are scheduled automatically by the service scheduling module 114. In some examples, the service scheduling module 114 waits for user confirmation (e.g., via the UI module 106) before proceeding with the scheduling.

At step 310, the system 100 continuously updates the user on the status of the repair process. In some examples, the updates are provided to the user via the UI module 106. In some examples, the updates include information provided by the component ordering module 112 and the service scheduling module 114.

At step 312, the system 100 notifies the user that the repairs have been completed. In some examples, the notification is provided to the user via the UI module 106.

At step 314, the system 100 collects feedback from technicians associated with the repairs. In some examples, the feedback is collected via the technician dispatch system of the service scheduling module 114 or the UI module 106. The feedback may convey the accuracy of: the predicted failures or diagnosis, the quantity of repairs ordered, the types of services scheduled, the number of technicians needed, the estimated repair time, the estimated repair costs, the types of components orders, and other information relevant to the monitoring and maintenance of the monitored devices 116.

At step 316, the collected feedback is integrated into the AI/ML models of the predictive analytics module 102. In some examples, the feedback is provided to the model training pipeline of the predictive analytics engine 102 to continuously train the AI/ML models. In some examples, such continuous training improves the accuracy of the AT/ML models.

As described above, an improved system for real-time monitoring and predictive maintenance of EV chargers is provided herein. The system 100 can minimize downtime of EV chargers through proactive maintenance, reducing the likelihood of unexpected failures. The system 100 may enhance the performance of EV chargers by scheduling regular maintenance to ensure hardware is operating at optimal performance. In some examples, the system 100 provides automated processes that reduce the costs associated with manual intervention. The system 100 may increase the reliability of EV chargers through real-time monitoring and predictive maintenance. In some examples, the labor needed to diagnose issues and make repairs is lowered by the system 100, reducing the need for highly skilled electricians specifically required in the EV industry.

### Hardware and Software Implementations

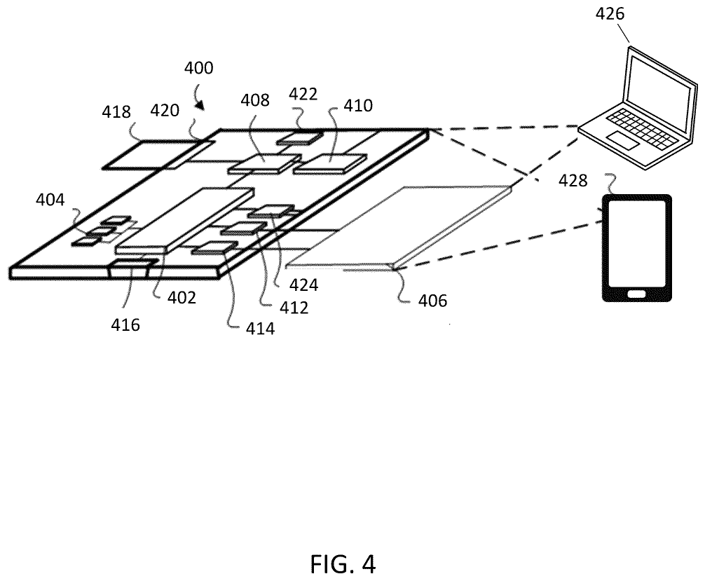

FIG. 4 shows an example of a generic computing device 400, which may be used with some of the techniques described in this disclosure. Computing device 400 includes a processor 402, memory 404, an input/output device such as a display 406, a communication interface 408, and a transceiver 410, among other components. The device 400 may also be provided with a storage device, such as a micro-drive or other device, to provide additional storage. Each of the components 400, 402, 404, 406, 408, and 410, are interconnected using various buses, and several of the components may be mounted on a common motherboard or in other manners as appropriate.

The processor 402 can execute instructions within the computing device 400, including instructions stored in the memory 404. The processor 402 may be implemented as a chipset of chips that include separate and multiple analog and digital processors. The processor 402 may provide, for example, for coordination of the other components of the device 400, such as control of user interfaces, applications run by device 400, and wireless communication by device 400.

Processor 402 may communicate with a user through control interface 412 and display interface 414 coupled to a display 406. The display 406 may be, for example, a TFT LCD (Thin-Film-Transistor Liquid Crystal Display) or an OLED (Organic Light Emitting Diode) display, or other appropriate display technology. The display interface 414 may comprise appropriate circuitry for driving the display 406 to present graphical and other information to a user. The control interface 412 may receive commands from a user and convert them for submission to the processor 402. In addition, an external interface 416 may be provided in communication with processor 402, so as to enable near area communication of device 400 with other devices. External interface 416 may provide, for example, for wired communication in some implementations, or for wireless communication in other implementations, and multiple interfaces may also be used.

The memory 404 stores information within the computing device 400. The memory 404 can be implemented as one or more of a computer-readable medium or media, a volatile memory unit or units, or a non-volatile memory unit or units. Expansion memory 418 may also be provided and connected to device 400 through expansion interface 420, which may include, for example, a SIMM (Single In Line Memory Module) card interface. Such expansion memory 418 may provide extra storage space for device 400, or may also store applications or other information for device 400. Specifically, expansion memory 418 may include instructions to carry out or supplement the processes described above, and may include secure information also. Thus, for example, expansion memory 418 may be provided as a security module for device 400, and may be programmed with instructions that permit secure use of device 400. In addition, secure applications may be provided via the SIMM cards, along with additional information, such as placing identifying information on the SIMM card in a non-hackable manner.

The memory may include, for example, flash memory and/or NVRAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 404, expansion memory 418, memory on processor 402, or a propagated signal that may be received, for example, over transceiver 410 or external interface 416.

Device 400 may communicate wirelessly through communication interface 408, which may include digital signal processing circuitry where necessary. Communication interface 408 may in some cases be a cellular modem. Communication interface 408 may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver 410. In addition, short-range communication may occur, such as using a Bluetooth, WiFi, or other such transceiver (not shown). In addition, GPS (Global Positioning System) receiver module 422 may provide additional navigation- and location-related wireless data to device 400, which may be used as appropriate by applications running on device 400.

Device 400 may also communicate audibly using audio codec 424, which may receive spoken information from a user and convert it to usable digital information. Audio codec 424 may likewise generate audible sound for a user, such as through a speaker, e.g., in a handset of device 400. Such sound may include sound from voice telephone calls, may include recorded sound (e.g., voice messages, music files, etc.) and may also include sound generated by applications operating on device 400. In some examples, the device 400 includes a microphone to collect audio (e.g., speech) from a user. Likewise, the device 400 may include an input to receive a connection from an external microphone.

The computing device 400 may be implemented in a number of different forms, as shown in FIG. 4. For example, it may be implemented as a computer (e.g., laptop) 426. It may also be implemented as part of a smartphone 428, smart watch, tablet, personal digital assistant, or other similar mobile device.

Some implementations of the subject matter and the operations described in this specification can be implemented in digital electronic circuitry, or in computer software, firmware, or hardware, including the structures disclosed in this specification and their structural equivalents, or in combinations of one or more of them. Implementations of the subject matter described in this specification can be implemented as one or more computer programs, i.e., one or more modules of computer program instructions, encoded on computer storage medium for execution by, or to control the operation of, data processing apparatus. Alternatively or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (e.g., multiple CDs, disks, or other storage devices).

The operations described in this specification can be implemented as operations performed by a data processing apparatus on data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language resource), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatus can also be implemented as, special purpose logic circuitry, e.g., an FPGA (field programmable gate array) or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing actions in accordance with instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, implementations of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending resources to and receiving resources from a device that is used by the user; for example, by sending web pages to a web browser on a user's client device in response to requests received from the web browser.

Implementations of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some implementations, a server transmits data (e.g., an HTML page) to a client device (e.g., for purposes of displaying data to and receiving user input from a user interacting with the client device). Data generated at the client device (e.g., a result of the user interaction) can be received from the client device at the server.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

While this specification contains many specific implementation details, these should not be construed as limitations on the scope of any inventions or of what may be claimed, but rather as descriptions of features specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

Thus, particular implementations of the subject matter have been described. Other implementations are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

What is claimed is:

1. A system for monitoring and maintaining electric vehicle (EV) chargers, comprising:
at least one memory for storing computer-executable instructions; and
at least one processor for executing the instructions stored on the at least one memory, wherein execution of the instructions programs the at least one processor to perform operations comprising:
receiving input data associated with at least one EV charger;
monitoring the input data via at least one artificial intelligence (AI) model;
detecting, via the at least one AI model, an anomaly in the input data, wherein the anomaly corresponds to a predicted failure of at least one component of the at least one EV charger;
automatically scheduling a repair;
in response to a determination that the repair has been completed, collecting feedback from at least one technician associated with the repair; and
providing the feedback to the at least one AI model, wherein the feedback is used to continuously train the at least one AI model to improve the accuracy of the at least one AI model.

2. The system of claim 1, wherein execution of the instructions programs the at least one processor to perform operations further comprising:
automatically ordering a replacement component.

3. The system of claim 2, wherein the replacement component is used in the repair.

4. The system of claim 2, wherein automatically scheduling a repair includes scheduling a repair based on (i) an availability of at least one technician and (ii) a lead time of the replacement component.

5. The system of claim 1, wherein execution of the instructions programs the at least one processor to perform operations further comprising:
determining that the at least one AI model inaccurately detected an anomaly based on the feedback from the at least one technician associated with the repair; and
in response to the determination, tuning the at least one AI model based on the inaccurate detection and the corresponding feedback.

6. The system of claim 1, wherein automatically scheduling a repair includes scheduling a repair based on a predicted failure date of the at least one component associated with the predicted failure.

7. The system of claim 1, wherein receiving input data associated with the at least one EV charger includes receiving, or requesting to receive, input data at a predetermined interval.

8. The system of claim 1, wherein receiving input data associated with the at least one EV charger includes receiving at least one of electrical data, operational data, environmental data, communication data, mechanical data, and user interaction data.

9. The system of claim 1, wherein receiving input data associated with the at least one EV charger includes receiving input data from a user associated with the at least one EV charger.

10. The system of claim 1, wherein execution of the instructions programs the at least one processor to perform operations further comprising:
generating an alert in response to detecting an anomaly that corresponds to a predicted failure of at least one component of the at least one EV charger; and
delivering the alert to at least one user associated with the at least one EV charger.

11. A method for monitoring and maintaining electric vehicle (EV) chargers, the method comprising:
receiving input data associated with at least one EV charger;
monitoring the input data via at least one artificial intelligence (AI) model;
detecting, via the at least one AI model, an anomaly in the input data, wherein the anomaly corresponds to a predicted failure of at least one component of the at least one EV charger;
automatically scheduling a repair;
in response to a determination that the repair has been completed, collecting feedback from at least one technician associated with the repair; and
providing the feedback to the at least one AI model, wherein the feedback is used to continuously train the at least one AI model to improve the accuracy of the at least one AI model.

12. The method of claim 11, further comprising:
automatically ordering a replacement component.

13. The method of claim 12, wherein the replacement component is used in the repair.

14. The method of claim 12, wherein automatically scheduling a repair includes scheduling a repair based on (i) an availability of at least one technician and (ii) a lead time of the replacement component.

15. The method of claim 11, further comprising:
determining that the at least one AI model inaccurately detected an anomaly based on the feedback from the at least one technician associated with the repair; and
in response to the determination, tuning the at least one AI model based on the inaccurate detection and the corresponding feedback.

16. The method of claim 11, wherein automatically scheduling a repair includes scheduling a repair based on a predicted failure date of the at least one component associated with the predicted failure.

17. The method of claim 11, wherein receiving input data associated with the at least one EV charger includes receiving, or requesting to receive, input data at a predetermined interval.

18. The method of claim 11, wherein receiving input data associated with the at least one EV charger includes receiving at least one of electrical data, operational data, environmental data, communication data, mechanical data, and user interaction data.

19. The method of claim 11, wherein receiving input data associated with the at least one EV charger includes receiving input data from a user associated with the at least one EV charger.

20. The method of claim 11, further comprising:
generating an alert in response to detecting an anomaly that corresponds to a predicted failure of at least one component of the at least one EV charger; and
delivering the alert to at least one user associated with the at least one EV charger.
